(19) United States
(12) Patent Application Publication
(10) Pub. No.: US 2013/0182264 A1
(43) Pub. Date: Jul. 18, 2013

(54) Projection Exposure Tool for Microlithography and Method for Microlithographic Exposure

(71) Applicants: Jochen Hetzler, Aalen (DE); Sascha Bleidistel, Aalen (DE); Toralf Gruner, Aalen-Hofen (DE); Joachim Hartjes, Aalen (DE)

(72) Inventors: Jochen Hetzler, Aalen (DE); Sascha Bleidistel, Aalen (DE); Toralf Gruner, Aalen-Hofen (DE); Joachim Hartjes, Aalen (DE)

(73) Assignee: Carl Zeiss SMT GmbH, Oberkochen (DE)

(21) Appl. No.: 13/788,042

(22) Filed: Mar. 7, 2013

Related U.S. Application Data
(63) Continuation of application No. PCT/EP2011/004750, filed on Sep. 22, 2011.
(60) Provisional application No. 61/387,267, filed on Sep. 28, 2010.

(30) Foreign Application Priority Data
Sep. 28, 2010 (DE) 10 2010 041558.8

(51) Int. Cl. G03F 7/20

(52) U.S. Cl. CPC G03F 7/70133
USPC 356/521

(57) ABSTRACT

A projection exposure tool for microlithography for exposing a substrate is disclosed. The tool includes a projection objective. The tool also includes an optical measuring apparatus for determining a surface topography of the substrate before the substrate is exposed. The measuring apparatus has a measuring beam path which extends outside of the projection objective. The measuring apparatus is a wavefront measuring apparatus configured to determine topography measurement values simultaneously at a number of points on the substrate surface.

### CROSS-REFERENCE TO RELATED APPLICATIONS

This application is a continuation of, and claims priority under 35 U.S.C. §120 to, International Patent Application Serial Number PCT/EP2011/004750, filed Sep. 22, 2011. International Patent Application Serial Number PCT/EP2011/004750 claims priority under 35 U.S.C. § 119(e) to U.S. Patent Application Ser. No. 61/387,267, filed Sep. 28, 2010, and also claims benefit under 35 U.S.C. §119 of German Patent Application No. 10 2010 041558.8, filed on Sep. 28, 2010. The entire disclosure of each of these patent applications is incorporated by reference in the present application.

### FIELD

The disclosure relates to a projection exposure tool for microlithography for exposing a substrate, in particular a wafer, and a method for the microlithographic exposure of a substrate via a projection exposure tool.

### BACKGROUND

For the high precision imaging of micro- or nanostructures with the aid of a lithography exposure tool it is important to know the position and the topography or the surface properties of the substrate to be exposed in order to always be able to keep the substrate in the best focus. In order to determine the position focus sensors are used, for example, which, during the exposure of the substrate in the area directly surrounding a substrate table, convey a measuring signal in almost grazing incidence onto the substrate plane and capture it again.

In order to measure the surface topography of the substrate measurement optics set up parallel to the projection optics are often used. Lithography exposure tools with such measurement optics often include two wafer tables or a so-called “tandem stage”. In these tools the surface topography of the substrate is initially measured on a measuring table using the measurement optics by point by point sampling or scanning of the substrate surface.

After this the substrate is loaded onto an exposure table and exposed. The exposed section of the substrate is held continuously in the best focus upon the basis of the surface topography measured. The deviations of the surface topography from an ideal planar surface are often in the micrometer range. Other lithography tools use two identical tables (“twin stage”) alternately as exposure and measuring tables. Reloading of the wafer is thus dispensed with.

The high wafer throughput with modern lithography tools involves a short measuring time of less than 30 seconds. For this purpose it is desirable to move the measuring table at high speeds and high accelerations during the topography measurement. The technical complexity for this purpose is considerable. Moreover, due to the high accelerations there is often an undesired transfer of vibrations of the measuring table to the exposure table with resulting image position errors with exposure of another wafer taking place simultaneously.

In lithography tools with just one table for measuring and exposing the measuring time is even more important. The measuring time goes directly into the throughput of the machine. Due to the ever more stringent desire properties for the wafer throughput the time budget for the topography measurement is further reduced.

### SUMMARY

The disclosure provides a projection exposure tool and a method for microlithographic exposure with which the surface topography of a substrate can be measured with a reduced measuring time without any negative impact upon the image quality during the substrate exposure.

In one aspect, the disclosure provides a projection exposure tool for micro lithography for exposing a substrate. The tool includes a projection objective and an optical measuring apparatus for determining a surface topography of the substrate before the latter is exposed. The measuring apparatus has a measuring beam path which extends outside of the projection objective. The measuring apparatus is a wavefront measuring apparatus configured to determine topography measurement values simultaneously at a number of points on the substrate surface.

In other words, the measuring apparatus is configured to take a locally resolved measurement at a discrete measuring time. A parallel measurement is thus taken at a number of points on the substrate surface. In other words, the surface topography is determined in turn by a two-dimensional measurement, i.e. topography measurement values are determined at a number of points on the substrate surface simultaneously. The surface topography of a substrate is understood as meaning the deviation of the surface from an ideal planar surface. The surface topography can also be called a height variation of the surface of the substrate.

The measuring apparatus is a wavefront measuring apparatus. Such a wavefront measuring apparatus may include a Shack-Hartmann wavefront sensor and/or an interferometer in the form of a two-dimensionally measuring interferometer, such as for example a Fizeau interferometer.

The measuring beam path of the measuring apparatus extends outside of the projection objective, i.e. outside of all of the optical elements involved in the imaging of a mask structure using the projection objective. In other words, the measuring beam path extends outside of the geometric region which contains the optical elements of the projection objective that are involved, i.e. outside of a casing containing all of the optical elements involved. In particular, the projection objective includes a housing, and the measuring beam path extends outside of the housing. Therefore, the measuring apparatus is not integrated into the projection objective, but is a separate device.

Using the simultaneous measurement of a number of points on the substrate surface using a wavefront measuring apparatus, the measuring time to measure the whole surface topography can be substantially reduced in comparison to conventionally used point by point measurement. Thus, whole regions of the substrate surface or even the whole substrate surface can be measured simultaneously. Therefore, the desire for speed and acceleration of the substrate during the measurement can be substantially reduced. One can thus in turn prevent vibrations of the measuring table from being transferred to an exposure table provided for simultaneous exposure of another substrate. Using the simultaneous measurement according to the disclosure the measuring time can even be reduced such that one can totally dispense with a second substrate table. The measurement and the exposure of the substrate can therefore be executed one after the other on the same substrate table without substantially reducing the substrate throughput by the previous measurement.

The projection exposure tool includes a projection objective for imaging mask structures onto the substrate. Depending on the exposure wavelength used, the projection objective includes lens elements and/or mirror elements. The measuring apparatus advantageously includes a recording device which records the whole surface topography of the substrate measured so that the topography measurement values are available for the subsequent exposure of the substrate.

In one embodiment, the measuring apparatus is configured to image, at least in sections, the substrate surface onto a detection surface of a locally resolving detector, e.g. in the form of a CCD camera.

In a further embodiment, the measuring apparatus is configured to image at least one section of the substrate surface onto a detection surface of a locally resolving detector. The imaged section encompasses a continuous area covering at least 2% (in particular at least 5%, especially at least 10% or at least 50%) of the entire substrate surface.

According to variants the continuous area covers at least 10 cm² (especially at least 50 cm² or at least 200 cm²). In a further embodiment, the projection exposure tool is configured for exposing a substrate, in particular a wafer, having a diameter of larger than 400 mm, in particular larger than 450 mm.

In a further embodiment, the measuring apparatus is configured to measure, in sections, the surface topography of the substrate. Furthermore, the measuring apparatus includes an evaluating device which is configured to combine the measurement results of the individual substrate sections. The simultaneously measured substrate sections can have, for example, a diameter of approximately 100 mm so that the measurement of a 300 mm wafer can be executed with approximately ten section measurements which are then combined by the evaluating device to form a topography distribution covering the whole substrate surface. Stitching methods known to the person skilled in the art can be applied here.

In a further embodiment, the measuring apparatus includes a detection region, in particular a continuous detection region, for simultaneous locally resolved detection of the substrate topography, the detection region having a surface expansion of at least 2% of the entire substrate surface. In other words the measuring apparatus is configured to measure the substrate topography by simultaneous locally resolved measurement in the detection region. The detection region may, according to some embodiments, have a surface expansion of at least 5%, at least 10% or at least 50% of the entire substrate surface. According to variants the detection region may have a surface expansion of at least 10 cm², especially at 50 cm² or at least 200 cm².

In a further embodiment, the projection exposure tool includes a substrate displacement apparatus for displacing the substrate between individual topography measurements so that different sections of the substrate can be measured one after the other. As already explained above, the measurements for the individual substrate sections are then combined. It is thus sufficient if the measuring apparatus has a detection region which only covers part of the substrate surface.

In a further embodiment, the substrate displacement apparatus is formed by an exposure tool of the projection exposure tool by which the substrate is held during exposure of the latter. In this embodiment one dispenses with a separate measuring table, and this substantially reduces the structural complexity for the projection exposure tool.

In an alternative embodiment, the substrate displacement apparatus is formed by a measuring table which is provided in the projection exposure tool in addition to an exposure table by which the substrate is held during exposure of the substrate. In this embodiment, the topography measurement of a substrate is taken simultaneously with the exposure of another substrate. It is thus possible to further increase the wafer throughput of a projection exposure tool because the measurement according to the disclosure is performed in a very short time, and so does not limit the wafer throughput which is even higher in the future.

According to a further embodiment, the measuring apparatus includes a Shack-Hartmann wavefront sensor. According to another embodiment, the measuring apparatus includes an interferometer, preferably in the form of a two-dimensionally measuring interferometer, such as for example a Fizeau interferometer. Such a two-dimensionally measuring interferometer allows a fast topography measurement of the whole substrate. According to a variant the measuring apparatus is an interferometer.

In a further embodiment, the measuring apparatus includes a light source for emitting measuring light and a curved mirror, in particular a parabolic mirror, for directing the measuring light onto the substrate surface.

In a further embodiment, the measuring apparatus is configured to determine the topography of the entire substrate surface within less than one second. Preferably, the measuring apparatus includes for this purpose a locally resolving detector that can detect 10 to 100 images per second.

In a further embodiment, the measuring apparatus is configured to irradiate measuring light at an oblique angle onto the substrate surface. An oblique angle is understood as being an angle deviating from 90° relative to the surface. Preferably the angle of incidence deviates by at least 10° ; in particular by at least 30° , and so e.g. by 60° from the 90° angle. Such a measuring apparatus irradiating measuring light at an oblique angle can be configured, for example, as a Mach-Zehnder interferometer.

In a further embodiment, the measuring apparatus includes a deflectometer which is configured to image a measurement structure onto a detector surface by reflection on the substrate surface. A stripe pattern, for example, can be used as a measurement structure. Such a stripe pattern can be configured one-dimensionally or two-dimensionally, for example in the form of a chessboard pattern.

In a further embodiment, the measuring apparatus is configured, within the framework of determining the surface topography, to measure the topography of a layer of the substrate close to the surface.

In a further embodiment, the optical measuring apparatus includes a light source having a spectral band being such that a layer thickness determination at the substrate surface can be made. For this purpose the interference effects on the layers with different wavelengths can be taken into account. Thus, e.g., thickness profiles of photoresist layers applied to a wafer or of other layers applied to a raw wafer can be measured.

In a further embodiment, the projection exposure tool further includes a control device which is configured to control the focus position of the exposure radiation during exposure of the substrate relative to the substrate surface upon the basis of the surface topography determined with the measuring apparatus. The focus position can be set, for example, by a relative displacement of the substrate in relation to the projection optics in the direction of the optical axis of the projection objective, by displacing the mask in the direction of the optical axis, by changing the distribution of the illumination radiation striking the mask, and/or by changing the optical properties of the projection objective.

In one aspect, the disclosure provides a method for the micro lithographic exposure of a substrate is provided. The method includes arranging the substrate in a beam path of an optical measuring apparatus and determining a surface topography of the substrate by simultaneously determining topography measurements at a number of points on the substrate surface via a wavefront measurement performed by the measuring apparatus. The method also includes changing the position of the substrate by rigid body movement in order to position the substrate in a beam path of exposure radiation of a projection exposure tool for microlithography. The method further includes exposing the substrate with the exposure radiation. The focus position of the exposure radiation relative to the substrate surface is controlled during the exposure upon the basis of the surface topography determined. Thus, the whole surface topography is determined before the substrate is exposed. With regard to advantages and further embodiments of the method according to the disclosure reference is made to the comments made above with regard to the projection exposure tool according to the disclosure. The wavefront measurement may be an interferometric measurement or a measurement using a Shack-Hartmann sensor.

The rigid body movement can include a displacement, rotation and/or tilt of the substrate.

According to one embodiment, the substrate is displaced in a plane lateral to the optical axis of the projection objective from a measuring position beneath the measuring apparatus into an exposure position beneath the projection objective.

The method is particularly useful for the measurement of large substrates. In an embodiment of the method according to the disclosure the substrate has a diameter of at least 400 nm, in particular at least 450 nm.

In one embodiment, the measuring apparatus is integrated into the projection exposure tool. According to a further embodiment the topography of the entire substrate surface is determined within less than one second.

Furthermore, in a further embodiment according to the disclosure a layer thickness determination at the substrate surface is made using the measuring apparatus.

The features specified with regard to the embodiments of the projection exposure tool according to the disclosure mentioned above can be applied correspondingly to the method according to the disclosure. Conversely, the features specified with regard to the embodiments of the method according to the disclosure mentioned above can be applied correspondingly to the projection exposure tool according to the disclosure.

### BRIEF DESCRIPTION OF THE DRAWINGS

The above and further advantageous features of the disclosure are illustrated in the following detailed description of exemplary embodiments with reference to the attached diagrammatic drawings, in which:

FIG. 1 an illustration of a projection exposure tool for microlithography with an embodiment according to the disclosure of a measuring apparatus for determining a surface topography of a substrate in the form of a wafer;

FIG. 2 a top view onto a wafer with an illustration of surface sections measured one after the other;

FIG. 3 a sectional view of a wafer;

FIG. 4 a further embodiment according to the disclosure of the measuring apparatus for determining a surface topography with a Shack-Hartmann sensor;

FIG. 5 a further embodiment according to the disclosure of the measuring apparatus for determining a surface topography in the form of a Fizeau interferometer with a parabolic mirror;

FIG. 6 a further embodiment according to the disclosure of the measuring apparatus for determining a surface topography in the form of a Mach-Zehnder interferometer;

FIG. 7 an illustration of the detection region of the measuring apparatus according to FIG. 6; and

FIG. 8 a further embodiment according to the disclosure of the measuring apparatus for determining a surface topography in the form of a deflectometer.

### DETAILED DESCRIPTION OF EXEMPLARY EMBODIMENTS

In the exemplary embodiments described below elements which are functionally or structurally similar to one another are provided as far as possible with the same or similar reference numbers. Therefore, in order to understand the features of the individual elements of a specific exemplary embodiment, one should refer to the description of other exemplary embodiments or to the general description of the disclosure.

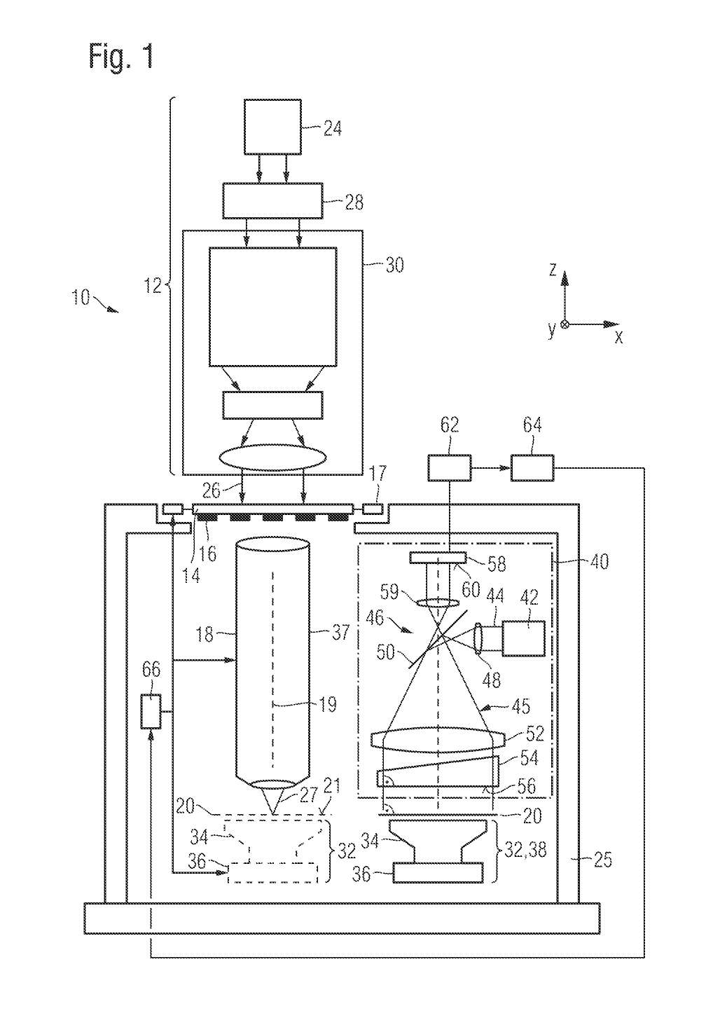

In order to facilitate the description of the projection exposure tool a Cartesian xyz coordinate system is specified in the drawings from which the respective relative position of the components shown in the drawings is made clear. In FIG. 1 the x direction extends to the right, the y direction perpendicularly to the plane of the drawing into the latter, and the z direction upwards.

In FIG. 1 a projection exposure tool 10 for microlithography in an embodiment according to the disclosure is shown. The projection exposure tool includes an illumination system 12 for illuminating a mask 14 with exposure radiation 26 and a projection objective 18. The projection objective 18 serves to image mask structures 16 on the mask 14 from a mask plane onto a substrate 20, e.g. in the form of a silicon wafer or a transparent so-called flat panel. For this purpose the projection objective 18 includes a number of optical elements, not shown in the drawings, for guiding the exposure radiation 26 in an exposure beam path 27. These optical elements which are thus involved in the imaging via the projection objective 18 are disposed in a geometric region which in the present embodiment is enclosed by a housing 37.

The illumination system 12 includes an exposure radiation source 24 for generating the exposure radiation 26. Depending on the embodiment of the projection exposure tool 10, the wavelength of the exposure radiation 26 can be in the UV wavelength range, e.g. at 248 nm or 193 nm, or also in the extreme ultraviolet wavelength range (EUV), e.g. at 13.5 or 6.8 nm. Depending on the exposure wavelength the optical elements of the illumination system 12 and of the projection objective 18 are designed as lenses and/or as mirrors.

The exposure radiation 26 generated by the exposure radiation source 24 passes through beam processing optics 28 and is then irradiated onto the mask 14 by an illuminator 30. The mask 14 is held by a mask table 17 which is displaceably mounted in relation to a frame 25 of the projection exposure tool 10. For the exposure the substrate 20 is disposed on an exposure table 32 which serves as a substrate displacement apparatus. In this position the substrate 20 is disposed in the exposure beam path 27, and so the exposure radiation strikes the substrate 20.

The exposure table 32 includes a substrate holder 34 for fixing the substrate 20 from the lower side of the latter, for example via negative pressure, and a displacement stage 36 by which the substrate can be displaced laterally to the optical axis 19 of the projection objective 18, i.e. in the x and y direction according to the coordinate system from FIG. 1.

Furthermore, the displacement stage 36 enables a displacement of the substrates 20 in the direction of the optical axis 19, and so in the z direction according to the coordinate system of FIG. 1. Such a displacement in the z direction serves in particular to hold the surface of the substrate 20 in the focus of the exposure radiation 26 when exposing the substrate 20.

Generally, the surface 21 of the substrate 20 is exposed section by section, i.e. field by field. Both the substrate 20 and the mask 14 are thereby moved in opposite directions along the x axis so that a slot-shaped exposure region is scanned over the substrate surface 21. This is performed a number of times so that the mask 14 is imaged in the form of a plurality of fields, one next to the other, on the substrate surface 21.

The substrate surface is not perfectly plane, but rather deviates considerably with regard to the depth of focus of the exposure radiation from a plane surface so that with the successive exposure of the substrate 20 the focus is continuously adapted to the profile of the surface topography of the substrate 20.

FIG. 3 shows an exemplary structure of a substrate 20 in the form of a wafer as a cross-section. The carrying element of the wafer forms a main body 22 which, depending on the procedural step, only includes the silicon base wafer 29 or also one or more further material layers 31 applied to the latter close to the surface, e.g. in the form of oxide or metal layers. A photosensitive layer in the form of a photoresist 23, which changes its chemical composition when exposed using the exposure radiation 26, is applied to the main body 22. In FIG. 3 one can see the aforementioned surface topography of the wafer which, depending on the embodiment, is characterised by the surface variation of the photoresist 23 or also of the main body 22.

There is integrated into the projection exposure tool 10 a measuring apparatus 40 which serves to determine the surface topography of the substrate 20 before the exposure of the substrate. In one embodiment the substrate 20 is disposed on the exposure table 32 beneath the measuring apparatus 40 in a measuring beam path 45 of the measuring apparatus 40. For this purpose the exposure table 32 is displaced into the position shown in FIG. 1 lateral to the optical axis 19 of the projection objective 18. In an alternative embodiment the projection exposure tool 10 includes a separate measuring table 38 the substrate 20 of which is positioned using the measuring apparatus 40 during the measurement while an already measured substrate 20 is simultaneously located on the exposure table 32 and is exposed in parallel.

The measuring apparatus 40 is designed as a two-dimensionally measuring optical measuring apparatus. In other words, when measuring the surface topography of the substrate 20 topography measurements are determined simultaneously at a number of points on the surface 21 in contrast to point by point sampling of the substrate surface 21.

In the following different embodiments of optical measuring apparatuses are proposed as a measuring apparatus 40. A first embodiment of the measuring apparatus 40 is shown in FIG. 1. According to this embodiment the measuring apparatus 40 includes a measuring light source 42 and two-dimensionally measuring interferometer in form of a Fizeau interferometer 46. The measuring light source 42 generates measuring light 44 e.g. in the visible wavelength range, such as for example light of a helium neon laser with a wavelength of 633 nm. Laser diodes, solid state lasers and LEDs can also be used as measuring light sources 42. The measuring light 44 is guided in the measuring beam path 45 and thereby passes through a collimator lens 48 and is then deflected by a beam splitter 50 in the direction of the substrate surface 21. Before striking the substrate surface the measuring light 44 passes through a further collimator lens 52 and a Fizeau element 54.

The Fizeau element 54 includes a Fizeau surface 56 on which part of the measuring light 44 is reflected back as reference light, while the non-reflected part of the measuring light 44 is reflected on the substrate surface 21 and then interferes with the reference light after passing through a further collimator lens 59 on a detection surface 60 of a locally resolving detector 58 in the form of a CCD camera.

In an alternative embodiment the collimator lens 52 and the Fizeau element 54 can be formed by a single optical element in the form of a Fizeau collimator. The interferogram on the detection surface 60 is detected by the detector 58. From the interferogram detected the surface profile of the section of the substrate surface 21 irradiated by the measuring light 44 is determined with an evaluating device 62. In other words, the surface topography of the substrate 20 is determined at least section by section.

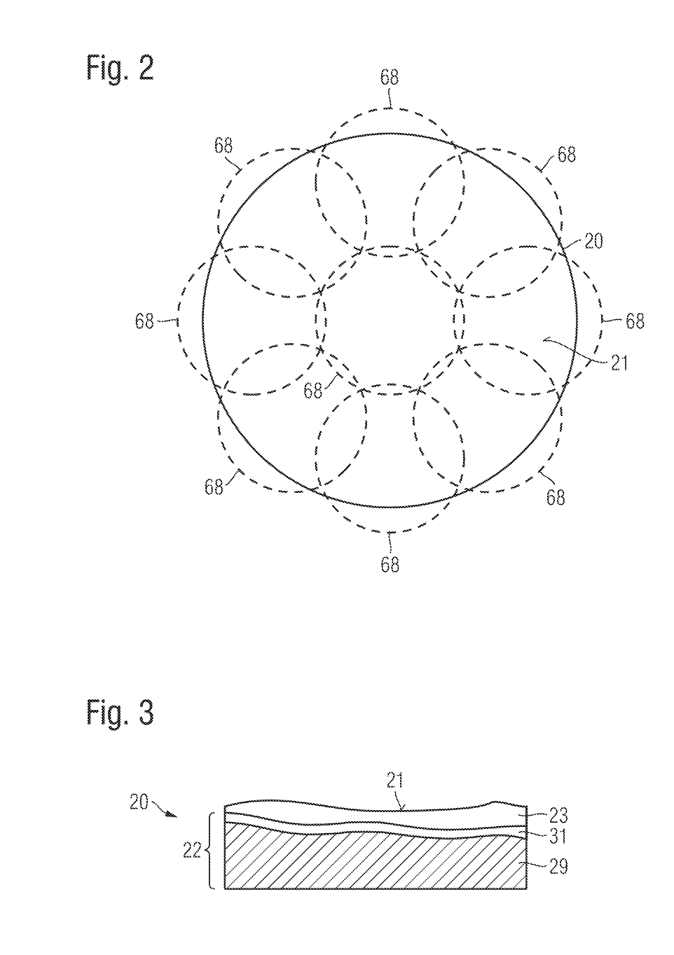

Here the detection region of the measuring apparatus 40, also called the sub-aperture, can be large enough to detect the whole substrate surface 21 at the same time. FIG. 2 shows an alternative embodiment according to which the detection region 68 of the measuring apparatus 40 only covers a partial region of the substrate surface 21. According to this embodiment the sections of the substrate surface 21 shown in FIG. 2 are detected one after the other by the measuring apparatus 40, and then the surface topography of the whole substrate is determined in the evaluating device 62 by combining the topography measurements for the individual measured substrate sections.

As shown in FIG. 2, the detection region 68 can be circular and have, for example, a diameter of approximately 100 mm. A 1000×1000 pixel CCD camera, for example, can be used as a corresponding locally resolving detector 58 with which a lateral resolution of the surface topography of 0.3 mm can then be achieved. The image detection rate of the

CCD camera is preferably 10 to 100 images. The axial measuring precision, i.e. the measuring precision perpendicular to the substrate surface can be approximately 1 nm.

The measured surface topography of the whole substrate 40 is then stored in a recording device 64 shown in FIG. 1. Furthermore, auxiliary structures are measured on the exposure table 32 using the measuring apparatus 40 in order to reference the axial position of the substrate 20 in the topography. For this purpose, however, the axial position of the substrate 20 is roughly known, in fact accurately enough in order to come into the capture range of the measuring apparatus 40. With the embodiment of the measuring apparatus 40 as an interferometer the capture range is 0.5 wavelengths of the measuring light 44. The axial position of the substrate 20 is therefore known accurately to 0.5 of a wavelength in order to be able to make use of the more precise interferometric measurement. This rough determination of the axial position is performed using an appropriate focus sensor, such as, e.g., a capacitive sensor.

After the topography measurement of the substrate 20 has been taken, the latter is displaced to beneath the projection objective 18. For this purpose, depending on the embodiment, reloading of the substrate 20 from the measuring table 38 onto the exposure table 32 is performed or, however, the substrate 40 remains on the exposure table which then changes its position. The axial distance of the substrate 20 in relation to the projection objective 18 is then set upon the basis of the above determined axial position measurements.

For the exposure of the substrate 20 which now follows the topography measurements are communicated by the recording device 64 to a control device 66. The control device 66 controls the focus position of the exposure radiation 26 during the exposure of the substrate 20. This is executed by controlling the exposure table 32, the mask table 17 and/or the projection objective 18 such that the focus of the exposure radiation 26 accurately follows the surface topography of the substrate 20.

As already mentioned above, the measuring light 44 can be substantially monochromatic, such as for example the light of a helium neon laser. Alternatively, the measuring light 44 can also have a wavelength spectrum spread to a number of nanometers so that a measurement based on white light interferometry can be performed. White light interferometry is described, for example, in Chapter 12 of the textbook “Basics of Interferometry” (second edition), P. Hariharan, Academic Press, September 2007. White light interferometry is particularly suitable when, instead of a conventional substrate in the form of a silicon wafer, a transparent medium such as for example a flat panel substrate is measured. Reflexes from the rear side of the panel do not interfere with the measurement in white light interferometry.

According to a further embodiment the topography measurement is taken with a number of wavelengths of the measuring light. Here the wavelengths are selected such that interference effects between the upper side of the layer and the lower side of the layer make it possible to measure the layer thickness profiles of the photoresist 23.

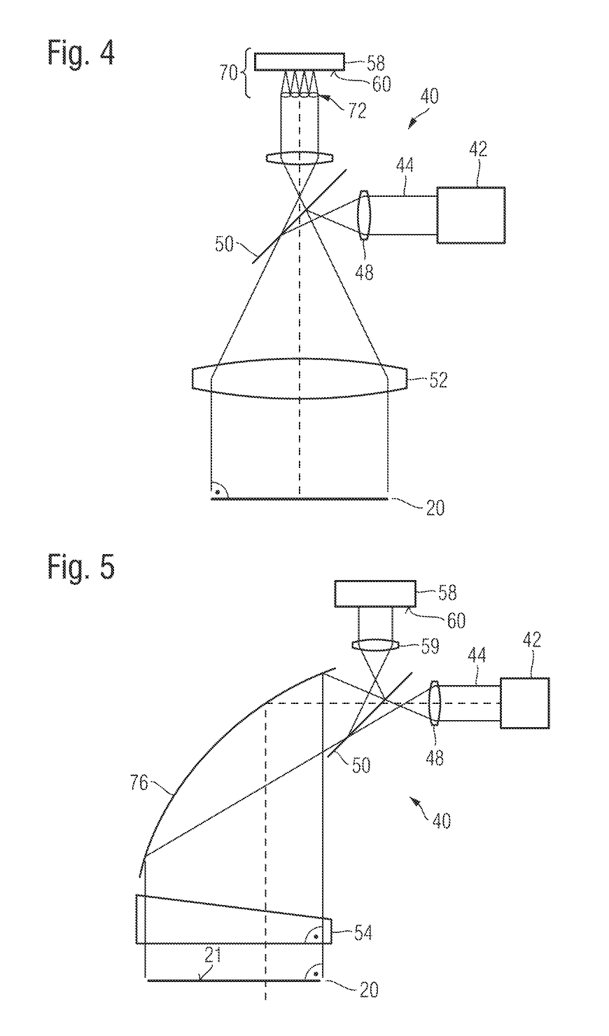

FIG. 4 shows a further embodiment of the measuring apparatus 40. The latter only differs from the measuring apparatus according to FIG. 1 in that the Fizeau element 54 is left out and a microlens array 72 is disposed upstream of the locally resolving detector 58. The microlens array 72 together with the detector 58 forms a so-called Shack-Hartmann sensor 70. Such a Shack-Hartmann sensor 70 is, like the Fizeau interferometer already described above, a wavefront measuring device with which deviations of the wavefront of the measuring light 44 reflected on the substrate surface from a plane wave can be determined. These deviations correspond to the surface topography of the substrate 20.

With a Shack-Hartmann wavefront sensor 70 it is not necessary to generate a reference wave. The micro lens array 72 generates small light points on the detection surface 60. The focal points of the light points define the local gradient of the wavefront. The wavefront is determined by two-dimensional integration.

FIG. 5 shows a further embodiment of the measuring apparatus 40 according to the disclosure. Like the measuring apparatus according to FIG. 1 the latter also includes a Fizeau interferometer and only differs from the embodiment according to FIG. 1 in that instead of the collimator lens 52, a parabolic mirror 76 is provided. In the embodiment according to FIG. 5 the measuring light 44 passes through the beam splitter 50 and is conveyed by the parabolic mirror 76 onto the substrate surface 20. The measuring radiation reflected on the substrate surface 21 and the reference radiation reflected on the Fizeau element are directed by the beam splitter onto the detection surface 60. This embodiment of the measuring apparatus 40 can be advantageous in respect of installation space or weight.

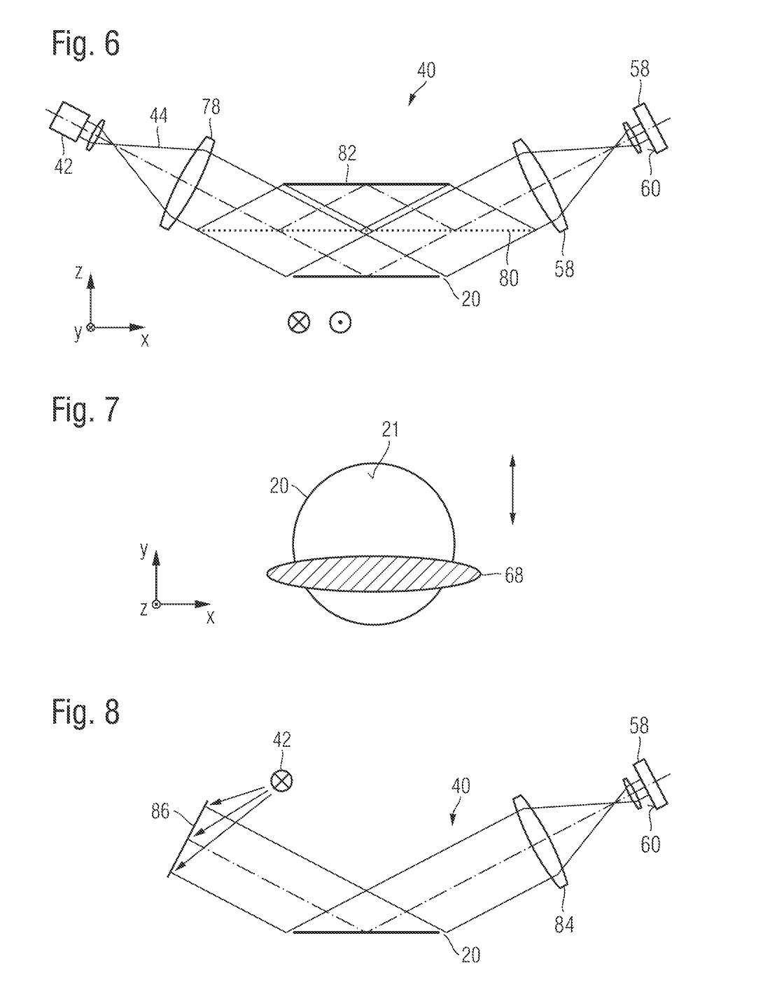

FIG. 6 shows a further embodiment of a measuring apparatus 40 according to the disclosure. The latter includes a so-called Mach-Zehnder interferometer. With the latter the measuring radiation 44 generated by the measuring light source 42 is irradiated using a collimator 78 at an oblique angle onto a beam splitter 80 which is disposed parallel to the substrate 20. The irradiation is executed such that part of the measuring light 44 is reflected by the beam splitter 80 as reference light onto a plane mirror 82 from which the reference light is thrown back onto the beam splitter 80 so that the light interferes with the part of the measuring light 44 which has passed through the beam splitter 80 on the detection surface 60 of the locally resolving detector 58 due to further reflection on the beam splitter 80.

With regard to variations of the interferometer according to FIG. 6 reference is made to “Semiconductor Wafer and Technical Flat Planes Testing Interferometer”, Johannes Schwider et al., Applied Optics Vol. 25, No. 7, pages 1117-1121 (1st April 1986). The advantage of the embodiment shown in FIG. 6 is a flat angle of incidence of the measuring light 44 onto the substrate surface and so an enlarged detection region 68 in the direction of the projection of the irradiation direction onto the substrate surface 21. The resulting detection region 68 is shown in FIG. 7. It is clearly evident from the figure that the expansion of the detection region 68 in the x direction in relation to the expansion of the latter in the y direction is greatly increased. In order to measure the substrate surface 21 it is sufficient to only move the substrate 20 in the y direction so that the substrate surface 21 is scanned successively from the detection region 68.

FIG. 8 shows a further embodiment of the measuring apparatus 40 which is designed in the form of a deflectometer. The latter includes a measurement structure 86 e.g. in the form of a fine chessboard lattice which is illuminated by the measuring light source 42. The measurement structure 86 is imaged onto the detection surface 60 of the locally resolving detector 58 by reflection on the substrate surface 21 via a collimator 84. A surface deformation of the substrate 20 leads to distorted imaging. The gradients of the surface 21 are proportional to the image distortion. With integration the surface topography of the substrate 20 is determined by using the evaluating device 62.

### LIST OF REFERENCE NUMBERS

10 projection exposure tool
12 illumination system
14 mask
16 mask structures
17 mask table
18 projection objective
19 optical axis
20 substrate
21 substrate surface
22 main body
23 photoresist
24 exposure radiation source
25 frame
26 exposure radiation
27 exposure beam path
28 beam processing optics
29 silicon base wafer
30 illuminator
31 material layer
32 exposure table
34 substrate holder
36 displacement stage
37 housing
38 measuring table
40 measuring apparatus
42 measuring light source
44 measuring light
45 measuring beam path
46 interferometer
48 collimator lens
50 beam splitter
52 collimator lens
54 Fizeau element
56 Fizeau surface
58 locally resolving detector
59 collimator lens
60 detection surface
62 evaluating device
64 recording device
66 control device
68 detection region
70 Shack-Hartmann sensor
72 microlens array
76 parabolic mirror
78 collimator
80 beam splitter
82 plane mirror
84 collimator
86 measurement structure

What is claimed is:

1. A tool, comprising:
a projection objective; and
an optical measuring apparatus configured to determine a surface topography of a substrate before the substrate is exposed via the projection objective,
wherein:
the optical measuring apparatus has a measuring beam path which extends outside of the projection objective;
the optical measuring apparatus is a wavefront measuring apparatus configured to determine topography measurement values simultaneously at a number of points on a surface of the substrate; and
the tool is a microlithography projection exposure tool.

2. The tool of claim 1, wherein the optical measuring apparatus comprises an interferometer.

3. The tool of claim 1, wherein the optical measuring apparatus is configured to image, at least in sections, the substrate surface onto a detection surface of a locally resolving detector.

4. The tool of claim 1, wherein:
the optical measuring apparatus is configured to measure, in sections, the surface topography of the substrate; and
the optical measuring apparatus comprises an evaluating device configured to combine the measurement results of the individual substrate sections.

5. The tool of claim 1, further comprising a displacement apparatus configured to displace the substrate between individual topography measurements so that different sections of the substrate are measurable one after the other.

6. The tool of claim 5, wherein the displacement apparatus is formed by an exposure table of the projection exposure tool by which the substrate is held during exposure of the latter.

7. The tool of claim 5, wherein the displacement apparatus comprises is a measuring table in the tool in addition to an exposure table by which the substrate is held during exposure of the substrate via the projection objective.

8. The tool of claim 1, wherein the optical measuring apparatus comprises a Shack-Hartmann wavefront sensor.

9. The tool of claim 1, wherein the optical measuring apparatus comprises a light source configured to emit measuring light, and the optical measuring apparatus comprises a curved mirror configured to direct the measuring light onto the substrate surface.

10. The tool of claim 1, wherein the optical measuring apparatus comprises a detection region for simultaneous locally resolved detection of the substrate topography, and the detection region comprises at least 2% of the entire substrate surface.

11. The tool of claim 1, wherein the optical measuring apparatus is configured to determine the topography of the entire substrate surface within less than one second.

12. The tool of claim 1, wherein the optical measuring apparatus is configured to irradiate measuring light at an oblique angle onto the substrate surface.

13. The tool of claim 1, wherein the optical measuring apparatus comprises a deflectometer configured to image a measurement structure onto a detector surface by reflection on the substrate surface.

14. The tool of claim 1, wherein the optical measuring apparatus is configured to measure the topography of a layer of the substrate close to the surface.

15. The tool of claim 1, wherein the optical measuring apparatus comprises a light source with a spectral band width so that a layer thickness determination at the substrate surface can be made.

16. The tool of claim 1, further comprising a control device configured to control a focus position of the exposure radiation during exposure of the substrate relative to the substrate surface upon the basis of the surface topography determined via the optical measuring apparatus.

17. A method, comprising:
arranging a substrate in a beam path of an optical measuring apparatus;
determining a surface topography of the substrate by simultaneously determining topography measurements at a number of points on surface of the substrate surface via a wavefront measurement performed by the optical measuring apparatus;
changing a position of the substrate by rigid body movement to position the substrate in a beam path of exposure radiation of a microlithography projection exposure tool; and
exposing the substrate with exposure radiation, a focus position of the exposure radiation relative to the substrate surface being controlled during the exposure based on the determined surface topography.

18. The method of claim 17, wherein the wavefront measurement comprises an interferometric measurement.

19. The method of claim 17, wherein the measuring apparatus is integrated into the projection exposure tool.

20. The method of claim 17, comprising determining the topography of the entire substrate surface within less than one second.

21. The of claim 17, further comprising determining a layer thickness at the substrate surface via the optical measuring apparatus.
